(19) United States
(12) Patent Application Publication
(10) Pub. No.: US 2024/0422949 A1
(43) Pub. Date: Dec. 19, 2024

(54) HEAT DISSIPATION STRUCTURE OF ELECTRONIC DEVICE

(71) Applicant: Delta Electronics, Inc., Taoyuan City (TW)

(72) Inventors: Po-Chen WU, Taoyuan City (TW); Shu-Hong CHU, Taoyuan City (TW); Ming-Tien LEE, Taoyuan City (TW); Yu-Hsuan SHA, Taoyuan City (TW); Tien-Lung CHAO, Taoyuan City (TW)

(21) Appl. No.: 18/500,151

(22) Filed: Nov. 2, 2023

(30) Foreign Application Priority Data
Jun. 15, 2023 (CN) 202310710764.9

(51) Int. Cl. H05K 7/20; H01L 23/40; H01R 13/518; H05K 1/18

(52) U.S. Cl. CPC H05K 7/20509; H01L 23/4006; H01R 13/518; H05K 1/18; H01L 2023/4087; H05K 2201/10189; H05K 2201/10409; H05K 2201/10424; H05K 2201/10522; H05K 2201/10545; H05K 2201/10598; H05K 2201/2009

(57) ABSTRACT

A heat dissipation structure of an electronic device is provided. The heat dissipation structure includes a substrate, connectors, clamps, a bracket and a heat sink. The substrate has a first surface and a second surface, and the first surface is provided with a control chip and connector holders. The connectors are disposed on the connector holders of the substrate. The clamps are used to affix the connectors to the substrate. The bracket is affixed to the substrate and has locking holes. The heat sink is affixed to the substrate through the locking holes of the bracket. The clamps are provided with elastic structures to respectively elastically press the upper surfaces of the connectors. The second surface of the substrate is provided with a stiffener to reinforce the strength of the substrate and provide heat conduction.

### CROSS REFERENCE TO RELATED APPLICATIONS

This Application claims priority of China Patent Application No. 202310710764.9, filed on Jun. 15, 2023, the entirety of which is incorporated by reference herein.

### BACKGROUND OF THE INVENTION

### Field of the Invention

The present invention relates to a heat dissipation structure of an electronic device, and, in particular, to a heat dissipation structure of an electronic device with a plurality of clamps.

### Description of the Related Art

Near-packaged optics (NPO) technology is to separate an optical engine (OE) from a switch chip. The two are assembled on the same printed circuit board (PCB) and an interlayer is added so that the signal routing from the switch chip to the optical engine is more convenient. The use of interlayer technology also means that the entire printed circuit board does not need to be upgraded, greatly reducing costs.

### BRIEF SUMMARY OF THE INVENTION

In accordance with one embodiment of the present disclosure, a heat dissipation structure of an electronic device is provided. The heat dissipation structure of an electronic device includes a substrate, a plurality of connectors, a plurality of clamps, a bracket and a heat sink. The substrate has a first surface and a second surface, and the first surface is provided with a control chip and a plurality of connector holders. Each of the connector holders has a first end and a second end, and the first ends are disposed towards the outer edge of the substrate. The connectors are disposed on the connector holders of the substrate, and a port of each of the connectors is located at the first end of each of the connector holders. The clamps are used to affix the connectors to the substrate. The bracket is affixed to the substrate, located at the second ends of the connector holders, and has a plurality of locking holes. The heat sink is affixed to the substrate through the locking holes of the bracket, and in contact with the control chip and the connectors on the substrate. The clamps are provided with a plurality of elastic structures to respectively elastically press the upper surfaces of the connectors. The second surface of the substrate is provided with a stiffener to reinforce the strength of the substrate and provide heat conduction.

In some embodiments, the substrate includes a printed circuit board (PCB).

In some embodiments, the connectors include optical engines (OEs) or electrical-signal connectors. In some embodiments, the connectors surround the control chip.

In some embodiments, the clamps are integrated or separated from each other. In some embodiments, each of the elastic structures has a first end and a second end, and one of the first end and the second end is embedded in the clamp. In some embodiments, each of the elastic structures has a first end and a second end, and the first end and the second end are embedded in the clamp.

In some embodiments, the bracket surrounds the control chip.

In some embodiments, the second surface of the substrate is provided with at least one power module and a plurality of second connectors. In some embodiments, the stiffener has a first surface and a second surface, the first surface has a plurality of recesses to accommodate the power module, and the second surface is provided with a plurality of fins. In some embodiments, a medium further fills between the recesses and the power module. In some embodiments, the heat dissipation structure of an electronic device is further disposed on a second substrate and electrically connected to the second substrate through the second connectors

### BRIEF DESCRIPTION OF THE DRAWINGS

The disclosure can be more fully understood from the following detailed description when read with the accompanying figures. It is worth noting that in accordance with standard practice in the industry, various features are not drawn to scale. In fact, the dimensions of the various features may be arbitrarily increased or reduced for clarity of discussion.

FIG. 1 shows an exploded view of a heat dissipation structure (e.g., optical signals) of an electronic device in accordance with one embodiment of the present disclosure;

FIG. 2 shows an exploded view of a heat dissipation structure (e.g., electrical signals) of an electronic device in accordance with one embodiment of the present disclosure;

FIG. 3 shows a stereogram of a partial structure of a heat dissipation structure of an electronic device in accordance with one embodiment of the present disclosure;

FIG. 4 shows a stereogram of a partial structure of a heat dissipation structure of an electronic device in accordance with one embodiment of the present disclosure;

FIG. 5 shows a schematic diagram of a bracket in a heat dissipation structure of an electronic device in accordance with one embodiment of the present disclosure;

FIG. 6 shows a stereogram of clamps in a heat dissipation structure of an electronic device in accordance with one embodiment of the present disclosure;

FIG. 7 shows a stereogram of a clamp in a heat dissipation structure of an electronic device in accordance with one embodiment of the present disclosure;

FIG. 8A shows a top view of a clamp in a heat dissipation structure of an electronic device in accordance with one embodiment of the present disclosure;

FIG. 8B shows a cross-sectional view of a clamp in a heat dissipation structure of an electronic device in accordance with one embodiment of the present disclosure;

FIG. 9A shows a top view of a clamp in a heat dissipation structure of an electronic device in accordance with one embodiment of the present disclosure;

FIG. 9B shows a cross-sectional view of a clamp in a heat dissipation structure of an electronic device in accordance with one embodiment of the present disclosure;

FIG. 10A shows an exploded view of a heat dissipation structure of an electronic device in accordance with one embodiment of the present disclosure;

FIG. 10B shows a top view of a partial structure of a heat dissipation structure of an electronic device in accordance with one embodiment of the present disclosure;

FIG. 10C shows a cross-sectional view of a partial structure of a heat dissipation structure of an electronic device in accordance with one embodiment of the present disclosure;

FIG. 11A shows a stereogram of a stiffener in a heat dissipation structure of an electronic device in accordance with one embodiment of the present disclosure;

FIG. 11B shows a stereogram of a stiffener in a heat dissipation structure of an electronic device in accordance with one embodiment of the present disclosure; and

FIG. 12 shows a stereogram of assembly of a partial structure of a heat dissipation structure of an electronic device and an external substrate in accordance with one embodiment of the present disclosure.

### DETAILED DESCRIPTION OF THE INVENTION

Various embodiments or examples are provided in the following description to implement different features of the present disclosure. The elements and arrangement described in the following specific examples are merely provided for introducing the present disclosure and serve as examples without limiting the scope of the present disclosure. For example, when a first component is referred to as “on a second component”, it may directly contact the second component, or there may be other components in between, and the first component and the second component do not come in direct contact with one another.

It should be understood that additional operations may be provided before, during, and/or after the described method. In accordance with some embodiments, some of the stages (or steps) described below may be replaced or omitted.

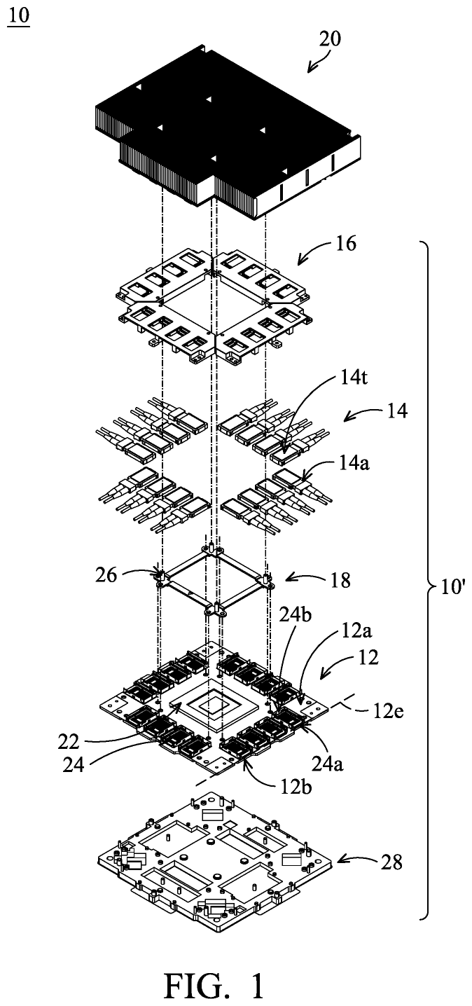

Referring to FIG. 1, in accordance with one embodiment of the present disclosure, a heat dissipation structure 10 of an electronic device is provided. FIG. 1 shows an exploded view of the heat dissipation structure 10 of the electronic device.

As shown in FIG. 1, the heat dissipation structure 10 of the electronic device includes a substrate 12, a plurality of connectors 14, a plurality of clamps 16, a bracket 18 and a heat sink 20. The substrate 12 has a first surface 12a and a second surface 12b, and the first surface 12a is provided with a control chip 22 and a plurality of connector holders 24. The number of connector holders 24 is not limited, for example, 16 connector holders (as the embodiment shown in FIG. 1). Each of the connector holders 24 has a first end 24a and a second end 24b, and the first ends 24a of the connector holders 24 are disposed towards an outer edge 12e of the substrate 12. The connectors 14 are disposed on the connector holders 24 of the substrate 12, and a port 14a of each of the connectors 14 is located at the first end 24a of each of the connector holders 24. The number of connectors 14 is not limited, and may be considered in conjunction with the number of connector holders, for example, 16 connectors (as the embodiment shown in FIG. 1). The clamps 16 are used to affix the connectors 14 to the substrate 12. The bracket 18 is affixed to the substrate 12, and located at the second ends 24b of the connector holders 24. The bracket 18 has a plurality of locking holes 26. The number of the locking holes 26 is not limited, for example, 4 locking holes (as the embodiment shown in FIG. 1). The structural profile of the bracket 18 will be described in detail later. The heat sink 20 is affixed to the substrate 12 through the locking holes 26 of the bracket 18. The clamps 16 are provided with a plurality of elastic structures (not shown) to respectively elastically press the upper surfaces 14t of the connectors 14. The above-mentioned elastic structure disposed in the clamps 16 will be described in detail later. The second surface 12b of the substrate 12 is provided with a stiffener 28 to reinforce the strength of the substrate 12 and provide heat conduction. The structural composition of the stiffener 28 will be described in detail later.

Not only do the clamps 16 affix the connectors 14 to the substrate 12, but they also provide an appropriate downward force to make the connection between the connectors 14 and the substrate 12 more firm. The heat sink 20 is locked and affixed to the substrate 12 through the locking holes 26 of the bracket 18. Since the locking holes 26 are located closer to the center of the overall package structure, for example, located around the control chip 22, it can reduce the warpage caused by the increase of the span when the heat sink 20 is locked by the locking holes 26 located closer to the peripheral position in the overall package structure. Since the fastening effect of the heat sink 20 is good, the heat dissipation effect of the heat sink 20 is also promoted. The bracket 18 also increases the rigidity of the substrate 12.

In some embodiments, the substrate 12 may include a printed circuit board (PCB).

In some embodiments, the connectors 14 may include optical engines (OEs) or electrical-signal connectors. In FIG. 1, the connectors 14 are optical engines (OEs), for example, optical engines with different transmission speeds. The connectors 14 surround the control chip 22.

In some embodiments, the clamps 16 may be integrated or separated from each other. In FIG. 1, the clamps 16 are separated from each other. The relevant structural compositions of the integrated clamps 16 and the separated clamps 16 will be described in detail later.

In FIG. 1, the bracket 18 surrounds the control chip 22.

The heat sink 20 can promote the heat dissipation of the connectors 14 and the control chip 22. In some embodiments, the heat sink 20 may be composed of an uniform-temperature board and fins or composed of heat pipes and fins. In FIG. 1, the heat sink 20 is composed of an uniform-temperature board and fins.

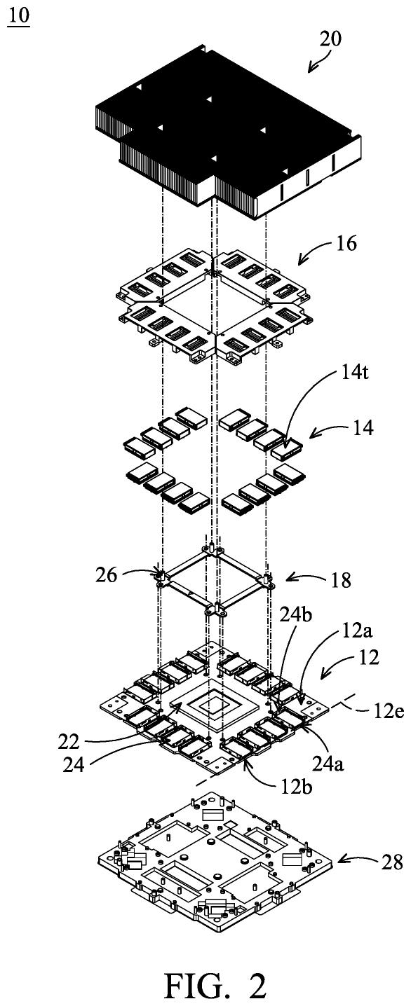

Referring to FIG. 2, in accordance with one embodiment of the present disclosure, a heat dissipation structure 10 of an electronic device is provided. FIG. 2 shows an exploded view of the heat dissipation structure 10 of the electronic device.

As shown in FIG. 2, the heat dissipation structure 10 of the electronic device includes a substrate 12, a plurality of connectors 14, a plurality of clamps 16, a bracket 18 and a heat sink 20. The substrate 12 has a first surface 12a and a second surface 12b, and the first surface 12a is provided with a control chip 22 and a plurality of connector holders 24. The number of connector holders 24 is not limited, for example, 16 connector holders (as the embodiment shown in FIG. 2). Each of the connector holders 24 has a first end 24a and a second end 24b, and the first ends 24a of the connector holders 24 are disposed towards an outer edge 12e of the substrate 12. The connectors 14 are disposed on the connector holders 24 of the substrate 12, and a port 14a of each of the connectors 14 is located at the first end 24a of each of the connector holders 24. The number of connectors 14 is not limited, and may be considered in conjunction with the number of connector holders, for example, 16 connectors (as the embodiment shown in FIG. 2). The clamps 16 are used to affix the connectors 14 to the substrate 12. The bracket 18 is affixed to the substrate 12, and located at the second ends 24b of the connector holders 24. The bracket 18 has a plurality of locking holes 26. The number of the locking holes 26 is not limited, for example, 4 locking holes (as the embodiment shown in FIG. 2). The structural profile of the bracket 18 will be described in detail later. The heat sink 20 is affixed to the substrate 12 through the locking holes 26 of the bracket 18. The clamps 16 are provided with a plurality of elastic structures (not shown) to respectively elastically press the upper surfaces 14t of the connectors 14. The above-mentioned elastic structure disposed in the clamps 16 will be described in detail later. The second surface 12b of the substrate 12 is provided with a stiffener 28 to reinforce the rigidity of the substrate 12 and provide heat conduction. The structural composition of the stiffener 28 will be described in detail later.

Not only does the clamp 16 affix the connectors 14 to the substrate 12, but it also provides an appropriate downward force to make the connection between the connectors 14 and the substrate 12 more firm. The heat sink 20 is locked and affixed to the substrate 12 through the locking holes 26 of the bracket 18. Since the locking holes 26 are located closer to the center of the overall package structure, for example, located around the control chip 22, it can reduce the warpage caused by the increase of the span when the heat sink 20 is locked by the locking holes 26 located closer to the peripheral position in the overall package structure. Since the fastening effect of the heat sink 20 is good, the heat dissipation effect of the heat sink 20 is also promoted. The bracket 18 also increases the rigidity of the substrate 12.

In some embodiments, the substrate 12 may include a printed circuit board (PCB).

In some embodiments, the connectors 14 may include optical engines (OEs) or electrical-signal connectors. In FIG. 2, the connectors 14 are electrical-signal connectors, for example, common connector socket (CCS) connectors. The connectors 14 surround the control chip 22.

In some embodiments, the clamps 16 may be integrated or separated from each other. In FIG. 2, the clamps 16 are separated from each other. The relevant structural compositions of the integrated clamps 16 and the separated clamps 16 will be described in detail later.

In FIG. 2, the bracket 18 surrounds the control chip 22.

The heat sink 20 can promote the heat dissipation of the connectors 14 and the control chip 22. In some embodiments, the heat sink 20 may be composed of an uniform-temperature board and fins or composed of heat pipes and fins. In FIG. 2, the heat sink 20 is composed of heat pipes and fins.

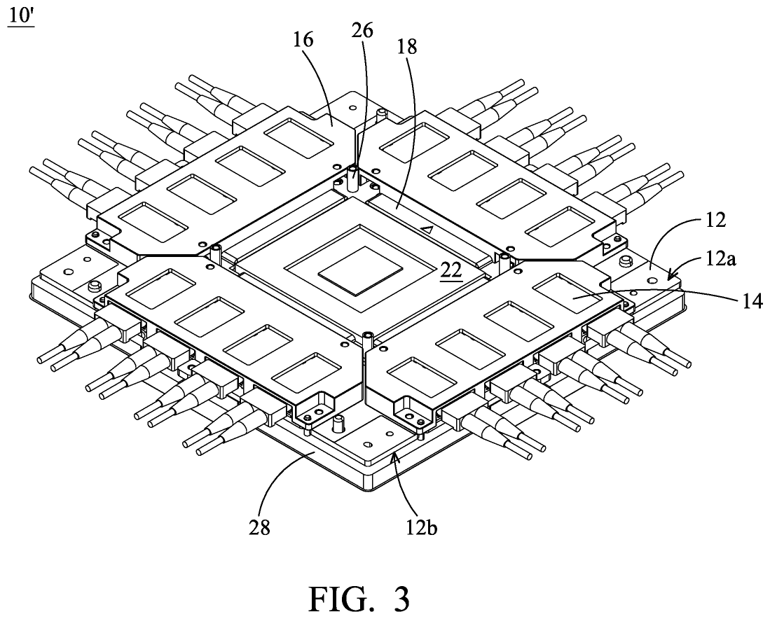

Referring to FIG. 3, in accordance with one embodiment of the present disclosure, a combination profile of a partial structure 10′ of the heat dissipation structure 10 of the electronic device as shown in FIG. 1 is further illustrated. FIG. 3 is a stereogram of the partial structure 10′ of the heat dissipation structure 10 of the electronic device, which includes the stiffener 28 located below the substrate 12, the substrate 12, the control chip 22 located above the substrate 12, the bracket 18, the connectors 14, and the clamps 16, etc.

As shown in FIG. 3, in the partial structure 10′ of the heat dissipation structure 10 of the electronic device, the first surface 12a of the substrate 12 is provided with a control chip 22 and the connectors 14 surrounding the control chip 22. The clamps 16 disposed on the substrate 12 are used for affixing the connectors 14 to the substrate 12. The bracket 18 is affixed to the substrate 12, surrounds the control chip 22, and has a plurality of locking holes 26. The heat sink (not shown) is affixed to the substrate 12 through the locking holes 26 of the bracket 18. The second surface 12b of the substrate 12 is provided with a stiffener 28 to reinforce the strength of the substrate 12 and provide heat conduction.

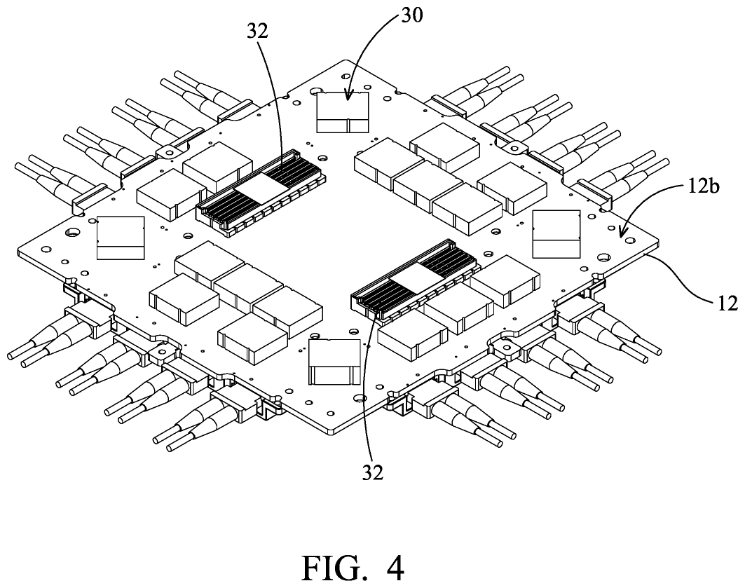

Referring to FIG. 4, in accordance with one embodiment of the present disclosure, the configuration on the second surface 12b of the substrate 12 in the heat dissipation structure 10 of the electronic device as shown in FIG. 1 is further illustrated. FIG. 4 is a stereogram of a partial structure of the heat dissipation structure 10 of the electronic device.

As shown in FIG. 4, in the partial structure of the heat dissipation structure 10 of the electronic device, the second surface 12b of the substrate 12 is provided with a plurality of power modules 30 and a plurality of second connectors 32. In some embodiments, the power modules 30 may include, for example, a plurality of DC-to-DC converters. The number of components constituting the power modules 30 is not limited, for example, 19 DC-to-DC converters (as the embodiment shown in FIG. 4). In some embodiments, The second connectors 32 may be used as board-to-board connectors to connect with an external substrate. The number of second connectors 32 is not limited, for example, 2 board-to-board connectors (as the embodiment shown in FIG. 4).

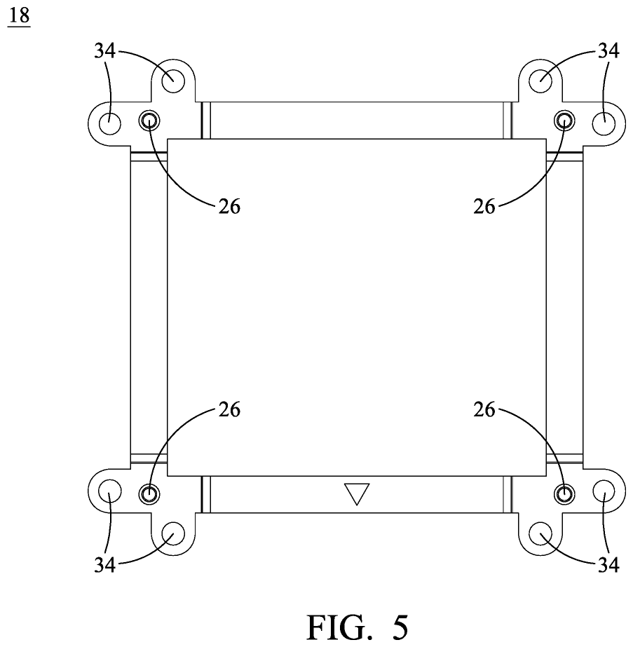

Referring to FIG. 5, in accordance with one embodiment of the present disclosure, the structural profile of the bracket 18 is further illustrated. FIG. 5 is a schematic diagram of the bracket 18 in the heat dissipation structure 10 of the electronic device.

As shown in FIG. 5, the bracket 18 includes a plurality of holes 34 and the locking holes 26. The holes 34 of the bracket 18 are used to affix the bracket 18 to the substrate 12. The number of holes 34 is not limited, for example, 8 holes (as the embodiment shown in FIG. 5). When considering locking the heat sink, due to the limitation of the layout of the substrate, it is impossible to add additional holes around the control chip on the substrate for the heat sink to be locked. In the present disclosure, the locking holes 26 of the bracket 18 are used to lock the heat sink without adding additional holes. On the one hand, the fastening effect of the heat sink 20 is improved, and on the other hand, the rigidity around the control chip can be increased.

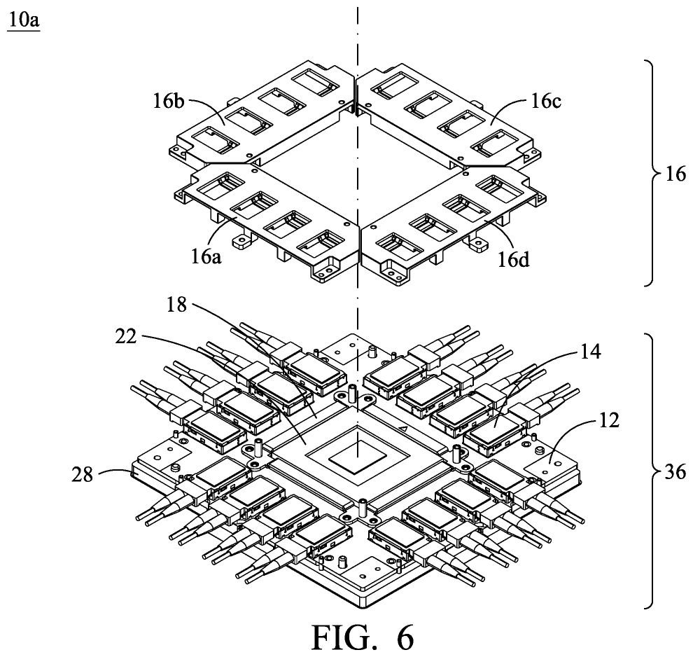

Referring to FIG. 6, in accordance with one embodiment of the present disclosure, the structural composition of the clamps 16 is further illustrated. FIG. 6 is a stereogram of a partial structure 10a of the heat dissipation structure 10 of the electronic component.

As shown in FIG. 6, in the partial structure 10a of the heat dissipation structure 10 of the electronic component, the situation that the clamps 16 are not yet engaged with the communication component 36 is taken as an example for illustration. The communication component 36 includes the stiffener 28 disposed below the substrate 12, the substrate 12, the control chip 22 disposed above the substrate 12, the bracket 18, and the connectors 14, etc. In FIG. 6, the clamps 16 are separated from each other, which includes a first portion 16a, a second portion 16b, a third portion 16c, and a fourth portion 16d, which are respectively used to affix the connectors 14 in the communication component 36. The separated clamps 16 do not overlap the bracket 18.

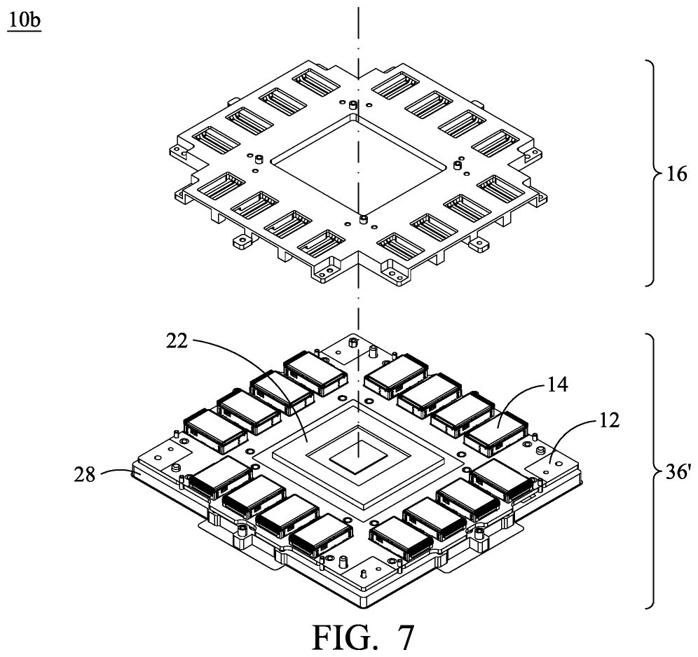

Referring to FIG. 7, in accordance with one embodiment of the present disclosure, the structural composition of the clamp 16 is further illustrated. FIG. 7 is a stereogram of a partial structure 10bof the heat dissipation structure 10 of the electronic component.

As shown in FIG. 7, in the partial structure 10bof the heat dissipation structure 10 of the electronic component, the situation that the clamp 16 is not yet engaged with the communication component 36′ is taken as an example for illustration. The communication component 36′ includes the stiffener 28 disposed below the substrate 12, the substrate 12, the control chip 22 disposed above the substrate 12, and the connectors 14, etc. In FIG. 7, the clamp 16 is integrated. For example, the bracket structure shown in FIG. 6 is integrated into the clamp 16. In addition to affixing the connectors 14 in the communication component 36′, the integrated clamp 16 can also lock the heat sink.

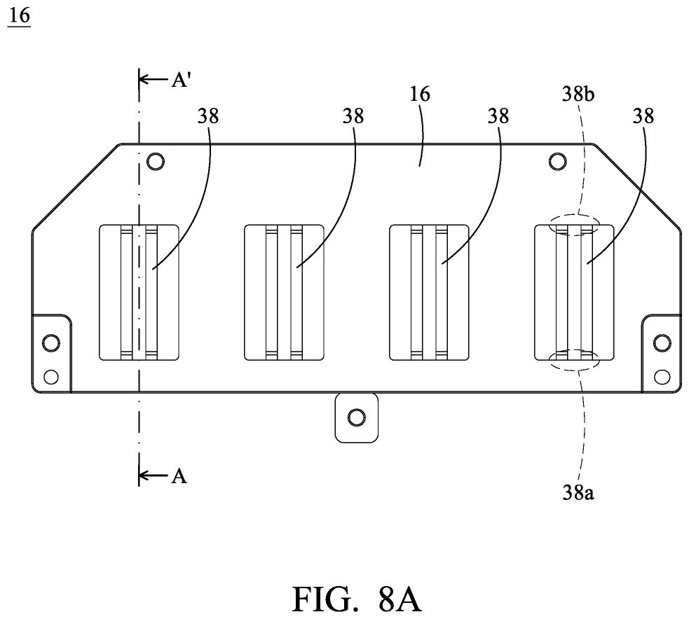

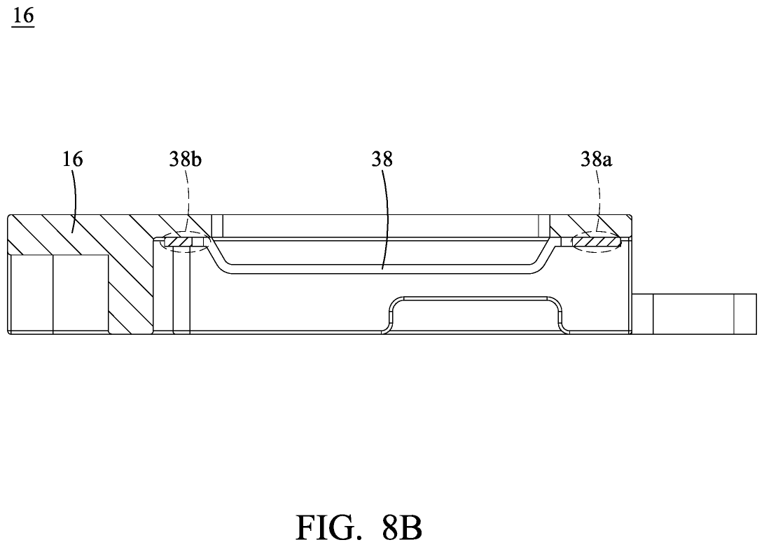

Referring to FIGS. 8A and 8B, in accordance with one embodiment of the present disclosure, the elastic structure 38 provided in the clamp 16 is further illustrated. FIG. 8A is a top view of the clamp 16 in the heat dissipation structure 10 of an electronic device. FIG. 8B is a cross-sectional view obtained along a cross-sectional line A-A′ of FIG. 8A.

As shown in FIGS. 8A and 8B, each of the elastic structures 38 in the clamp 16 has a first end 38a and a second end 38b, and at least one of the first end 38a and the second end 38b of the elastic structure 38 is embedded in the clamp 16. In the embodiment shown in FIGS. 8A and 8B, the first end 38a and the second end 38b of the elastic structure 38 are embedded in the clamp 16.

The clamp 16 as shown in FIGS. 8A and 8B can provide appropriate positive pressure for each connector, and the elastic structures 38 in the clamp 16 can further control the positive force of pressing down, so that the connectors can be firmly affixed to the substrate.

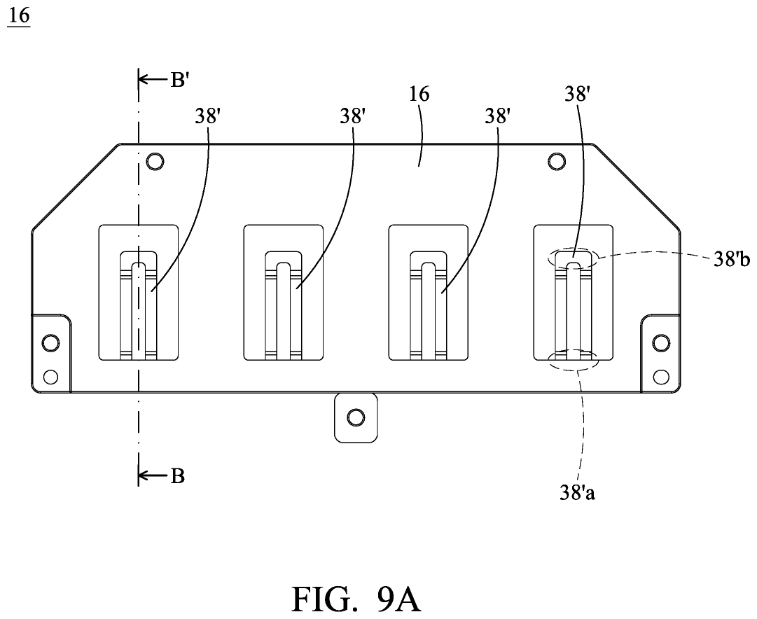

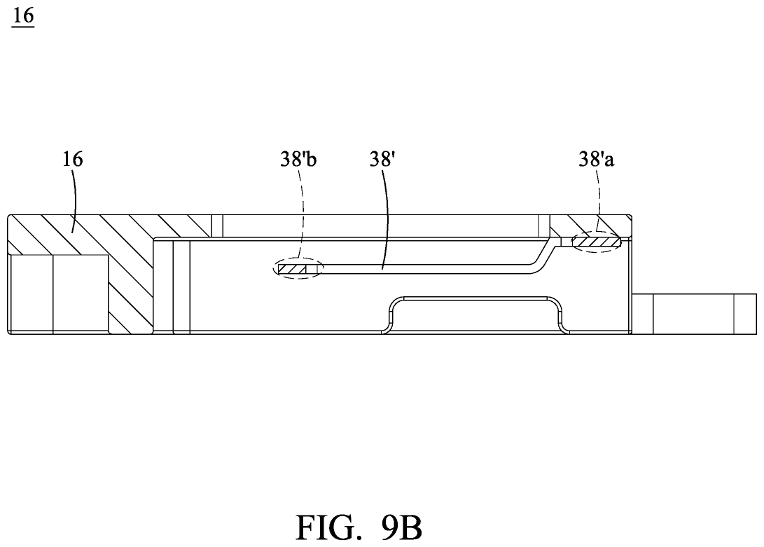

Referring to FIGS. 9A and 9B, in accordance with one embodiment of the present disclosure, the elastic structure 38′ provided in the clamp 16 is further illustrated. FIG. 9A is a top view of the clamp 16 in the heat dissipation structure 10 of an electronic device. FIG. 9B is a cross-sectional view obtained along a cross-sectional line B-B′ of FIG. 9A.

As shown in FIGS. 9A and 9B, each of the elastic structures 38′ in the clamp 16 has a first end 38′a and a second end 38′b, and at least one of the first end 38′a and the second end 38′b of the elastic structure 38′ is embedded in the clamp 16. In the embodiment shown in FIGS. 9A and 9B, the first end 38′a of the elastic structure 38′ is embedded in the clamp 16, while the second end 38′b is suspended and not embedded in the clamp 16.

The clamp 16 as shown in FIGS. 9A and 9B can provide appropriate positive pressure for each connector, and the elastic structures 38′ in the clamp 16 can further control the positive force of pressing down, so that the connectors can be firmly affixed to the substrate.

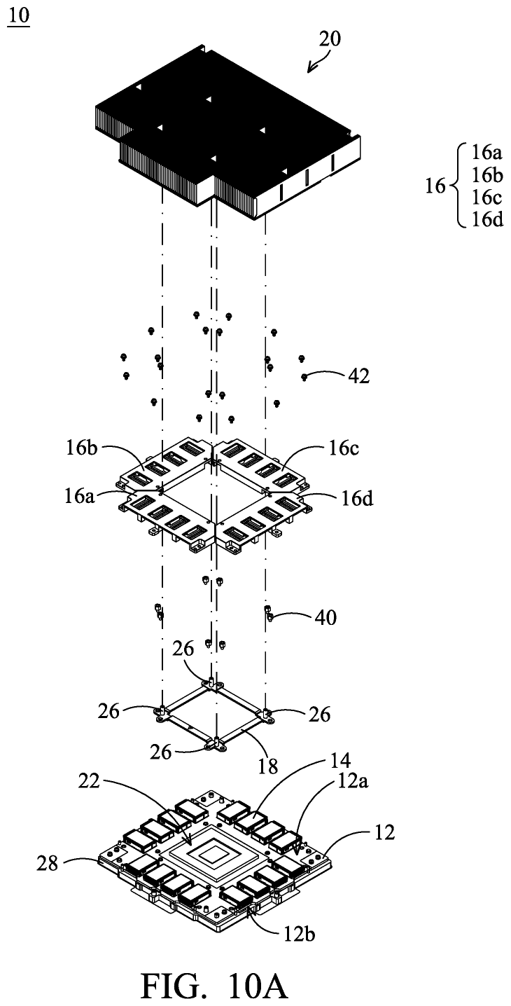

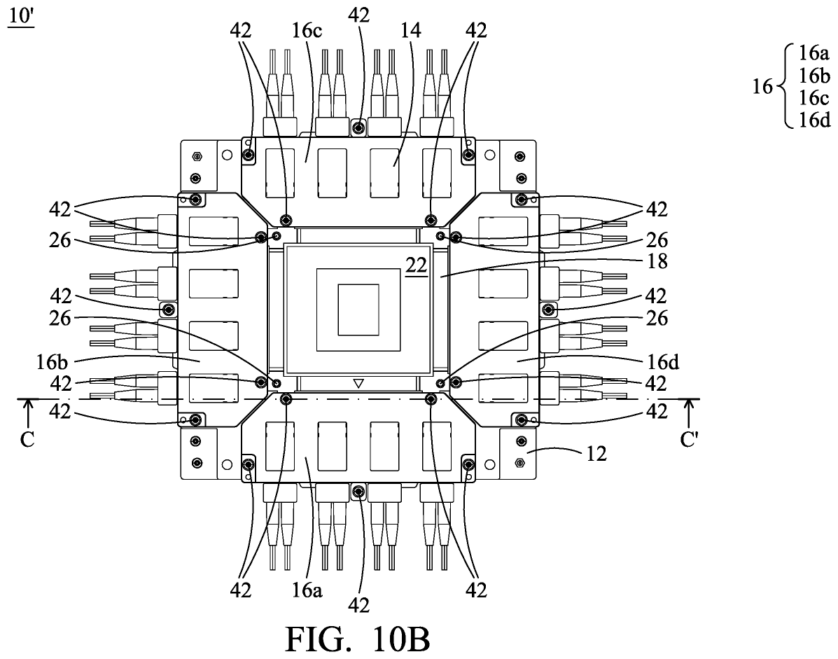

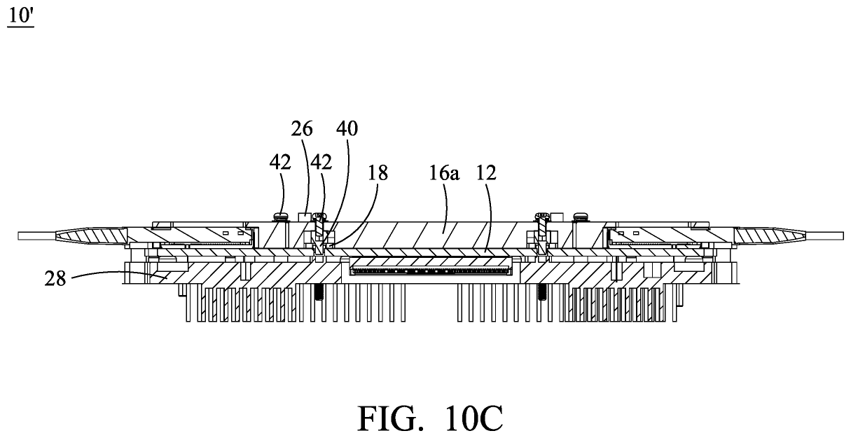

Referring to FIGS. 10A, 10B and 10C, in accordance with one embodiment of the present disclosure, the assembly sequence of the bracket 18, the connectors 14, the clamps 16, and the heat sink 20 and the arrangement relationship among the components in the heat dissipation structure 10 of the electronic device are further illustrated. FIG. 10A is an exploded view of the heat dissipation structure 10 of the electronic device. FIG. 10B is a top view of the partial structure 10′ of the heat dissipation structure 10 of the electronic device. FIG. 10C is a cross-sectional view obtained along a cross-sectional line C-C′ of FIG. 10B.

As shown in FIG. 10A, the assembly of the bracket 18, the connectors 14, the clamps 16, and the heat sink 20 is performed. First, the bracket 18 is locked on the first surface 12a (the upper surface) of the substrate 12 by eight standoffs 40, and is affixed around the control chip 22. The bracket 18 has four locking holes 26 for subsequent locking of the heat sink 20. The second surface 12b (the lower surface) of the substrate 12 opposite to the bracket 18 is provided with a stiffener 28. After that, the connectors 14 are assembled on the substrate 12. Afterwards, the separated clamps 16 (including the first portion 16a, the second portion 16b, the third portion 16c, and the fourth portion 16d) are locked on the substrate 12 by twenty screws 42 (divided into four groups in total), so as to affix the connectors 14 around the control chip 22. Afterwards, the heat sink 20 is locked on the bracket 18 through four spring screws (not shown) and through the locking holes 26 of the bracket 18. So far, the assembly of the heat dissipation structure 10 of the electronic device is completed.

As shown in FIG. 10B, from a top view, the arrangement relationship among the components on the substrate 12 is further illustrated. The bracket 18 is locked on the substrate 12 by eight standoffs (not shown), and is fixed around the control chip 22. The bracket 18 has four locking holes 26 for subsequent locking of the heat sink 20. The separated clamps 16 (including the first portion 16a, the second portion 16b, the third portion 16c, and the fourth portion 16d) are locked on the substrate 12 by, for example, 20 screws 42 (divided into four groups in total), so as to affix the connectors 14 around the control chip 22.

As shown in FIG. 10C, from a cross-sectional view, the lower surface of the substrate 12 is provided with a stiffener 28. The bracket 18 is locked on the substrate 12 by the standoffs 40. The bracket 18 has the locking holes 26 for subsequent locking of the heat sink 20. The separated clamps 16 (for example, the first portion 16a) are locked on the substrate 12 by the screws 42.

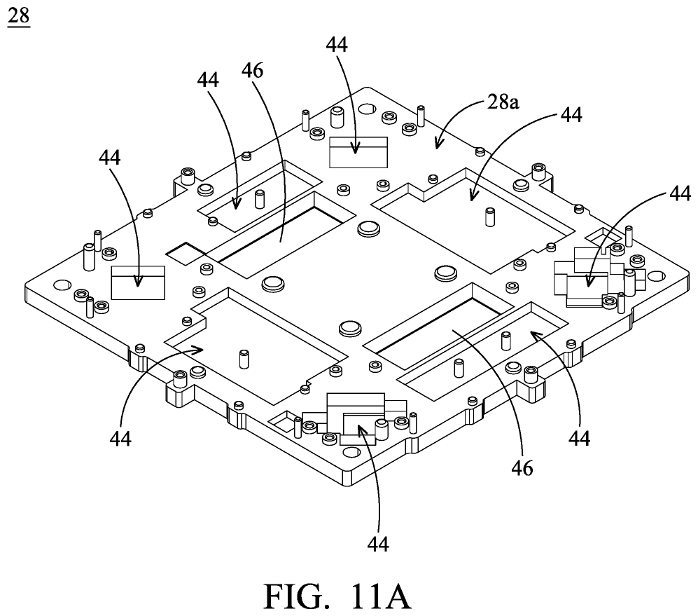

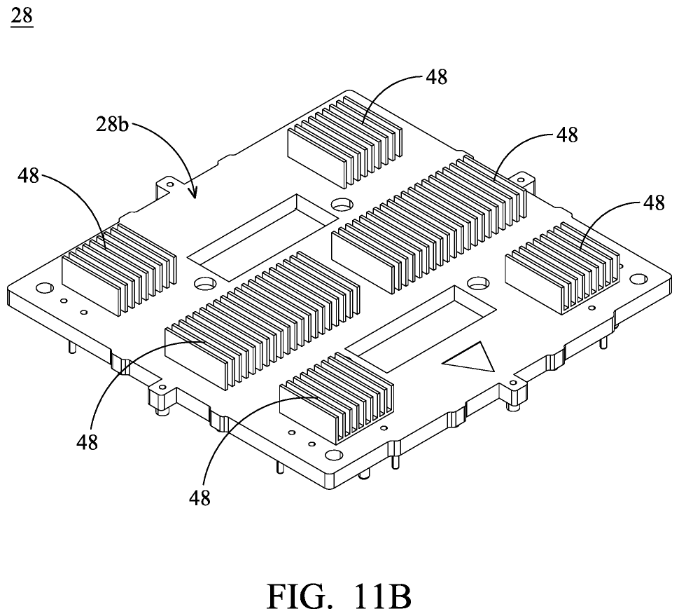

Referring to FIGS. 11A and 11B, in accordance with one embodiment of the present disclosure, the structural composition of the stiffener 28 is further illustrated. FIGS. 11A and 11B are stereograms of the stiffener 28 in the heat dissipation structure 10 of the electronic device.

As shown in FIG. 11A, the first surface 28a of the stiffener 28 has a plurality of recesses 44 and a plurality of openings 46. The recesses 44 of the stiffener 28 can be used to accommodate the power modules 30 arranged on the second surface 12b of the substrate 12 as shown in FIG. 4, for example, to accommodate 19 DC-to-DC converters. In some embodiments, the spaces between the recesses 44 and the power modules 30 further include medium, such as gap filler. On the one hand, various assembly tolerances can be absorbed; on the other hand, the heat released from the power modules 30 can be transferred to the stiffener 28. The number of recesses 44 of the stiffener 28 is not limited, for example, 8 recesses (as the embodiment shown in FIG. 11A), which mainly depends on the number of components of the power modules 30. In addition, the second connectors 32 disposed on the second surface 12b of the substrate 12 as shown in FIG. 4 may be exposed from the openings 46 of the stiffener 28. The exposed second connectors 32 may be further connected to an external substrate.

As shown in FIG. 11B, the second surface 28b of the stiffener 28 is provided with a plurality of fins 48. When the heat released by the power modules 30 is transferred to the stiffener 28, the fins 48 disposed on the second surface 28b can achieve a heat dissipation effect through conduction.

In the present disclosure, the stiffener 28 disposed on the bottom of the substrate 12 not only has the function of conduction and heat dissipation, but also can reinforce the rigidity of the entire substrate.

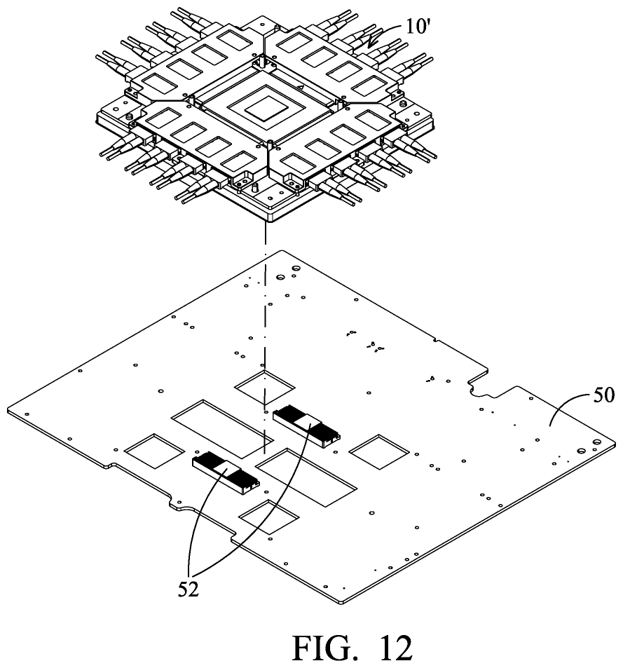

Referring to FIG. 12, in accordance with one embodiment of the present disclosure, the assembly of the partial structure 10′ of the heat dissipation structure 10 of the electronic device and an external substrate is further illustrated. FIG. 12 is a stereogram of assembly of the partial structure 10′ of the heat dissipation structure 10 of the electronic device and the external substrate.

As shown in FIG. 12, the partial structure 10′ of the heat dissipation structure 10 of the electronic device is arranged on the second substrate 50 (i.e. the external substrate). The partial structure 10′ of the heat dissipation structure 10 of the electronic device is electrically connected to the second substrate 50 by assembling the second connectors (not shown) disposed on the second surface of the substrate in the partial structure 10′ of the heat dissipation structure 10 of the electronic device and the third connectors 52 of the second substrate 50. In some embodiments, the second substrate 50 may include a printed circuit board (PCB). Although some embodiments of the present disclosure and their advantages have been described in detail, it should be understood that various changes, substitutions and alterations can be made herein without departing from the spirit and scope of the disclosure as defined by the appended claims. The features of the various embodiments can be used in any combination as long as they do not depart from the spirit and scope of the present disclosure. Moreover, the scope of the present application is not intended to be limited to the particular embodiments of the process, machine, manufacture, composition of matter, means, methods and steps described in the specification. As one of ordinary skill in the art will readily appreciate from the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods or steps. In addition, each claim constitutes an individual embodiment, and the claimed scope of the present disclosure includes the combinations of the claims and embodiments. The scope of protection of present disclosure is subject to the definition of the scope of the appended claims. Any embodiment or claim of the present disclosure does not need to meet all the purposes, advantages, and features disclosed in the present disclosure.

What is claimed is:

1. A heat dissipation structure of an electronic device, comprising:
a substrate having a first surface and a second surface, wherein the first surface of the substrate is provided with a control chip and a plurality of connector holders, each of the connector holders has a first end and a second end, and the first ends of the connector holders are disposed towards an outer edge of the substrate;
a plurality of connectors disposed on the connector holders of the substrate, wherein a port of each of the connectors is located at the first end of each of the connector holders;
a plurality of clamps used to affix the connectors to the substrate;
a bracket affixed to the substrate, located at the second ends of the connector holders, and having a plurality of locking holes; and
a heat sink affixed to the substrate through the locking holes of the bracket.

2. The heat dissipation structure of an electronic device as claimed in claim 1, wherein the substrate comprises a printed circuit board (PCB).

3. The heat dissipation structure of an electronic device as claimed in claim 1, wherein the connectors comprise optical engines or electrical-signal connectors.

4. The heat dissipation structure of an electronic device as claimed in claim 1, wherein the connectors surround the control chip.

5. The heat dissipation structure of an electronic device as claimed in claim 1, wherein the clamps are integrated or separated from each other.

6. The heat dissipation structure of an electronic device as claimed in claim 1, wherein the bracket surrounds the control chip.

7. The heat dissipation structure of an electronic device as claimed in claim 1, wherein the clamps are provided with a plurality of elastic structures to respectively elastically press upper surfaces of the connectors.

8. The heat dissipation structure of an electronic device as claimed in claim 7, wherein each of the elastic structures has a first end and a second end, and at least one of the first end and the second end of the elastic structure is embedded in the clamp.

9. The heat dissipation structure of an electronic device as claimed in claim 1, wherein the second surface of the substrate is provided with at least one power module and a plurality of second connectors.

10. The heat dissipation structure of an electronic device as claimed in claim 9, wherein the second surface of the substrate is provided with a stiffener to reinforce strength of the substrate and provide heat conduction.

11. The heat dissipation structure of an electronic device as claimed in claim 10, wherein the stiffener has a first surface and a second surface, the first surface of the stiffener has a plurality of recesses to accommodate the power module, and the second surface of the stiffener is provided with a plurality of fins.

12. The heat dissipation structure of an electronic device as claimed in claim 9, wherein the heat dissipation structure of an electronic device is further disposed on a second substrate and electrically connected to the second substrate through the second connectors.
